(19) United States
(12) Patent Application Publication
(10) Pub. No.: US 2025/0322888 A1
(43) Pub. Date: Oct. 16, 2025

(54) MEMORY DEVICE AND OPERATING METHOD THEREOF

(71) Applicant: SK hynix Inc., Gyeonggi-do (KR)

(72) Inventor: Jong Wook KIM, Gyeonggi-do (KR)

(21) Appl. No.: 18/893,973

(22) Filed: Sep. 24, 2024

(30) Foreign Application Priority Data
Apr. 12, 2024 (KR) 10-2024-0049359

(51) Int. Cl. G11C 16/26; G06F 12/02; G11C 16/04; G11C 16/08; G11C 16/10; G11C 16/24; G11C 16/30

(52) U.S. Cl. CPC G11C 16/26; G06F 12/0223; G11C 16/0483; G11C 16/08; G11C 16/10; G11C 16/24; G11C 16/30

(57) ABSTRACT

A memory device and an operating method thereof are provided. The memory device includes a memory cell array including a plurality of memory cells; a peripheral circuit for performing a program operation and a read operation on the plurality of memory cells; a temperature detection circuit for generating a temperature code by measuring a temperature of the memory cell array after a program command is externally received; and a control logic for setting, based on the temperature code, at least one of a level of operating voltages and a bit line precharge level, and controlling, in response to the program command, the peripheral circuit to perform the program operation on the plurality of memory cells, using at least one of the level of the operating voltages and the bit line precharge level.

### CROSS-REFERENCE TO RELATED APPLICATION

The present application claims priority under 35 U.S.C. § 119(a) to Korean patent application number 10-2024-0049359 filed on Apr. 12, 2024, the entire disclosure of which is incorporated by reference herein.

### BACKGROUND

### 1. Field of Invention

Embodiments of the present disclosure generally relate to an electronic device, and more particularly, to a memory device and an operating method thereof.

### 2. Description of Related Art

The paradigm for the recent computer environment has been turned into ubiquitous computing environment in which computing systems can be used anywhere and anytime. This promotes increasing usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A data storage device using a memory device has excellent stability and durability, high information access speed, and low power consumption, since there is no mechanical driving part. In an example of memory systems having such advantages, the data storage device includes a Universal Serial Bus (USB) memory device, memory cards having various interfaces, a Solid State Drive (SSD), and the like.

Memory devices are generally classified into volatile memory devices and nonvolatile memory devices.

A nonvolatile memory device has relatively slow write and read speeds, but retains stored data even when the supply of power is interrupted. Thus, the nonvolatile memory device is used to store data to be retained regardless of whether power is supplied. Examples of the nonvolatile memory include a Read Only Memory (ROM), a Mask ROM (MROM), a Programmable ROM (PROM), an Erasable Programmable ROM (EPROM), an Electrically Erasable and Programmable ROM (EEPROM), a flash memory, a Phase-change RAM (PRAM), a Magnetic RAM (MRAM), a Resistive RAM (RRAM), a Ferroelectric RAM (FRAM), and the like. Flash memories are classified into NOR type flash memories and NAND type flash memories.

The nonvolatile memory device controls a memory cell by generating bit line operating voltages and word line operating voltages during a program operation and a read operation. When the bit line operating voltages and the word line operating voltages, which are used for control of the memory cell, are not adjusted according to temperature, an error may occur in sensing data stored in the memory cell.

### SUMMARY

Embodiments of the present disclosure provide a memory device and an operating method thereof, which can reduce or minimize an error between a temperature measured in a temperature measurement operation for a program operation of the memory device and a temperature measured in a temperature measurement operation for a read operation of the memory device.

In accordance with an embodiment of the present disclosure, there is provided a memory device including a memory cell array including a plurality of memory cells; a peripheral circuit configured to perform a program operation and a read operation on the plurality of memory cells; a temperature detection circuit configured to generate a temperature code by measuring a temperature of the memory cell array after a program command is externally received; and a control logic configured to set, based on the temperature code, at least one of a level of operating voltages and a bit line precharge level, and control, in response to the program command, the peripheral circuit to perform the program operation on the plurality of memory cells, using at least one of the level of the operating voltages and the bit line precharge level, wherein, when a read command is externally received after completing the program operation and a program elapsed time is within a set time, the control logic is configured to set at least one of a level of operating voltages and a bit line precharge level which are to be used in a read operation corresponding to the read command, based on the temperature code generated after receiving the program command, when a program elapsed time is within a set time.

In accordance with another embodiment of the present disclosure, there is provided a method of operating a memory device, the method including receiving a first command corresponding to a first operation; measuring, after the first command is received, a temperature inside the memory device; generating a first temperature code corresponding to the measured temperature; setting first operating voltages used in the first operation, based on the first temperature code; performing the first operation using the set first operating voltages; setting second operating voltages used in a second operation based on the first temperature code, when a second command corresponding to the second operation is received within a set time after completing the first operation; and performing the second operation using the set second operating voltages.

In accordance with still another embodiment of the present disclosure, there is provided a method of operating a memory device, the method including receiving a first command corresponding to a program operation; measuring a temperature inside the memory device; generating a first temperature code corresponding to the measured temperature; setting first operating voltages used in the program operation, based on the first temperature code; performing the program operation using the set first operating voltages; receiving a second command corresponding to a read operation after completing the program operation; measuring a program elapsed time according to a time point of reception of the second command; setting second operating voltages to be used in the read operation, using the first temperature code, and performing the read operation using the set second operating voltages when the program elapsed time is within a set time.

In accordance with still another embodiment of the present disclosure, there is provided a memory device including a memory block; a voltage generating circuit configured to apply operating voltages to word lines of the memory block in a program operation and a read operation on the memory block; a page buffer group configured to precharge bit lines of the memory block in the program operation and the read operation; a temperature detection circuit configured to generate a first temperature code by measuring a temperature inside the memory device after receiving a program command, and generate a second temperature code by newly measuring a temperature inside the memory device when a read command corresponding to the read operation is received, exceeding a set time, after completing the program operation; and a control logic configured to set, based on the first temperature code or the second temperature code, at least one of a level of the operating voltages and a bit line precharge level, and control, in response to the program command or the read command, the voltage generating circuit and the page buffer group to perform the program operation or the read operation, using at least one of the set level of the operating voltages and the bit line precharge level, wherein, when the read command corresponding to the read operation is received within the set time after completing the program operation, the control logic is configured to set at least one of the level of operating voltages and the bit line precharge level which are to be used in the read operation, based on the first temperature code.

### BRIEF DESCRIPTION OF THE DRAWINGS

Various embodiments of the present disclosure will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system in accordance with an embodiment of the present disclosure.

FIG. 2 is a diagram illustrating a memory device shown in FIG. 1.

FIG. 3 is a diagram illustrating a memory block shown in FIG. 2.

FIG. 4 is a diagram illustrating a three-dimensionally configured memory block in accordance with an embodiment of the present disclosure.

FIG. 5 is a flowchart illustrating a program operation and a read operation of the memory device shown in FIG. 2.

FIG. 6 is a diagram illustrating a memory system in accordance with an embodiment of the present disclosure.

FIG. 7 is a diagram illustrating a memory system in accordance with an embodiment of the present disclosure.

FIG. 8 is a diagram illustrating a memory system in accordance with an embodiment of the present disclosure.

FIG. 9 is a diagram illustrating a memory system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and should not be construed as limited to the embodiments set forth herein.

Hereinafter, embodiments of the present disclosure will be described in detail with reference to the accompanying drawings in order for those skilled in the art to be able to readily implement the technical spirit of the present disclosure.

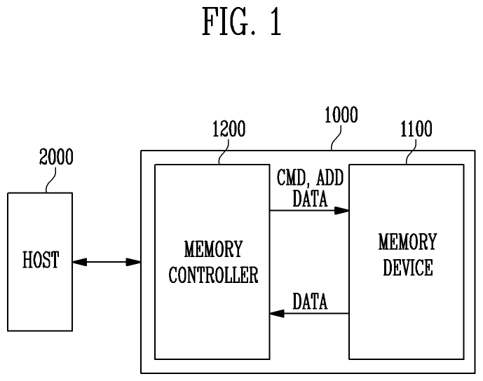

FIG. 1 is a diagram illustrating a memory system in accordance with an embodiment of the present disclosure.

Referring to FIG. 1, the memory system 1000 may include a memory device 1100 in which data is stored and a memory controller 1200 which controls the memory device 1100 under the control of a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or Serial Attached SCSI (SAS). In addition, the interface protocol between the host 2000 and the memory system 1000 are not limited to the above-described examples, and may be one of other interface protocols such as a Universal Serial Bus (USB), a Multi-Media Card (MMC), an Enhanced Small Disk Interface (ESDI), and an Integrated Drive Electronics (IDE).

The memory controller 1200 may control overall operations of the memory system 1000, and control data exchange between the host 2000 and the memory device 1100. For example, the memory controller 1200 may control the memory device 1100 to program or read data according to a request of the host 2000. In a program operation, the memory controller 1200 may transmit, to the memory device 1100, a command CMD corresponding to the program operation, an address ADD, and data DATA to be programmed. Also, in a read operation, the memory controller 1200 may receive and temporarily store data DATA read from the memory device 1100, and transmit the temporarily stored data DATA to the host 2000.

The memory device 1100 may perform a program, read or erase operation under the control of the memory controller 1200. When a command CMD corresponding to a program operation is received from the memory controller 1200, the memory device in accordance with an embodiment of the present disclosure may perform a temperature measurement operation in response to the command CMD, set a level of operating voltages used in the program operation, based on a temperature code corresponding to a temperature measured as a result of the temperature measurement operation, and perform the program operation, using the operating voltages having the set level. Also, when a command CMD corresponding to a read operation is received from the memory controller 1200 after the program operation is completed, the memory device 1100 may set a level of operating voltages used in the read operation, based on a temperature code obtained as a result of a temperature measurement operation performed before the program operation according to a time from a time point at which the program operation is completed to a time point at which the command CMD corresponding to the read operation is received, or obtain a new temperature code by performing a new temperature measurement operation and set a level of operating voltages used in the read operation, based on the new temperature code.

In some embodiments, the memory device 1100 may include a Double Data Rate Synchronous Dynamic Random Access Memory (DDR SDRAM), a Low Power Double Data Rate4 (LPDDR4) SDRAM, a Graphics Double Data Rate (GDDR) SDRAM, a Low Power DDR (LPDDR), a Rambus Dynamic Random Access Memory (RDRAM), or a flash memory.

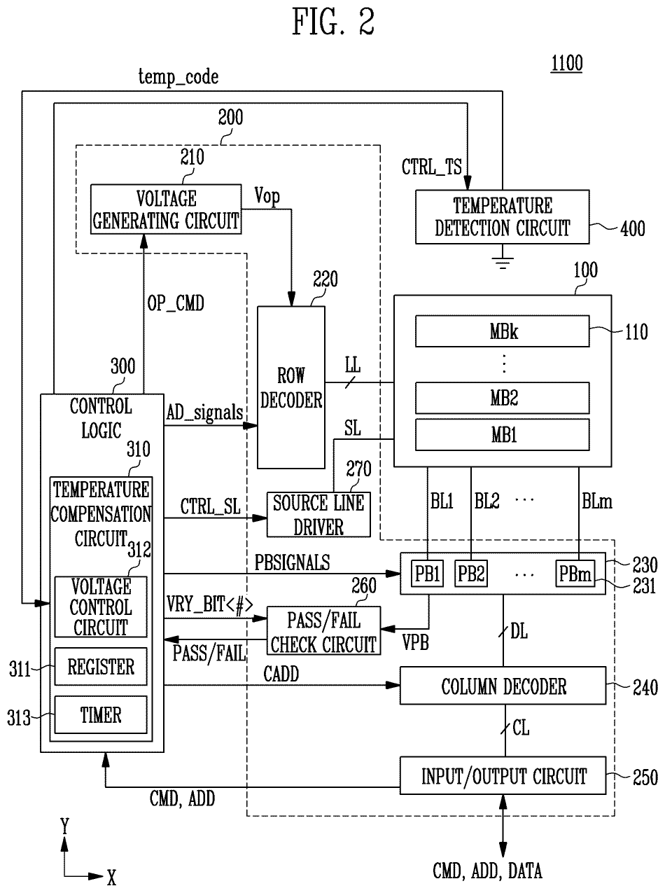

FIG. 2 is a diagram illustrating the memory device shown in FIG. 1.

Referring to FIG. 2, the memory device 1100 may include a memory cell array 100 in which data is stored. The memory device 1100 may include a peripheral circuit 200 configured to perform a program operation for storing data in the memory cell array 100, a read operation for outputting stored data, and an erase operation for erasing stored data. The memory device 1100 may include a control logic 300 which controls the peripheral circuit 200 under the control of the memory controller (1200 shown in FIG. 1). The memory device 1100 may include a temperature detection circuit 400 for detecting a temperature of the memory device 1100, and the control logic 300 may set a level of operating voltages Vop used in the program operation and the read operation, based on a temperature of the memory cell array 100, which is detected by the temperature detection circuit 400.

The memory cell array 100 may include a plurality of memory blocks MB1 to MBk 110, where k is a positive integer. Local lines LL and the bit lines BL1 to BLm, where m is a positive integer, may be connected to each of the memory blocks MB1 to MBk 110. For example, the local lines LL may include a first select line, a second select line, and a plurality of word lines arranged between the first and second select lines. Also, the local lines LL may include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be connected to each of the memory blocks MB1 to MBk 110, and the bit lines BL1 to BLm may be commonly connected to the memory blocks MB1 to MBk 110. The memory blocks MB1 to MBk 110 may be implemented in a two-dimensional or three-dimensional structure. For example, memory cells may be arranged in a direction parallel to a substrate in the memory blocks 110 having the two-dimensional structure. For example, memory cells may be stacked in a direction vertical to a substrate in the memory blocks 110 having the three-dimensional structure.

The peripheral circuit 200 may be configured to perform program, read, and erase operations of a selected memory block 110 under the control of the control logic 300. For example, the peripheral circuit 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program, read, and erase operations in response to an operation signal OP_CMD. In an embodiment, the voltage generating circuit 210 may adjust a level of operating voltages Vop generated in a program operation and a level of operating voltages Vop generated in a read operation under the control of a temperature compensation circuit 310 included in the control logic 300. The voltage generating circuit 210 may include a pump.

The row decoder 220 may transfer operating voltages Vop to the local lines LL connected to the selected memory block 110 in response to row decoder control signals AD_signals. For example, in a program operation, the row decoder 220 may apply a program operating voltage generated by the voltage generating circuit 210 to word lines of the selected memory block 110 in response to the row decoder control signals AD_signals. Also, in a read operation, the row decoder 220 may apply a read operating voltage generated by the voltage generating circuit 210 to the word lines of the selected memory block 110 in response to the row decoder control signals AD_signals.

The page buffer group 230 may include a plurality of page buffers PB1 to PBm 231 connected to the bit lines BL1 to BLm. The page buffers PB1 to PBm 231 may operate in response to page buffer control signals PBSIGNALS. For example, in a program operation, the page buffers PB1 to PBm 231 may temporarily store data to be programmed and control a potential level of the bit lines BL1 to BLm, based on the temporarily stored data to be programmed. Also, in a read operation, the page buffers PB1 to PBm 231 may sense data stored in memory cells included in the selected memory block 110 by sensing potential levels or current amounts of the bit lines BL1 to BLm.

In an embodiment, the page buffers PB1 to PBm 231 may precharge the bit lines BL1 to BLm by adjusting a precharge level of the bit lines BL1 to BLm to a set level in the program operation and the read operation under the control of the temperature compensation circuit 310 included in the control logic 300.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are transferred from the memory controller (1200 shown in FIG. 1), to the control logic 300, or exchange data DATA with the column decoder 240.

In a read operation or a program verify operation, the pass/fail check circuit 260 may generate a reference current in response to an allow bit VRY_BIT<#>, and output a pass signal PASS or a fail signal FAIL by comparing a sensing voltage VPB received from the page buffer group 230 with a reference voltage generated by the reference current. The sensing voltage VPB may be a voltage controlled based on a number of memory cells determined as pass in the program verify operation.

The source line driver 270 may be connected to a memory cell included in the memory cell array 100 through the source line SL, and control a voltage applied to the source line SL. The source line driver 270 may receive a source line control signal CTRL_SL from the control logic 300, and control a source line voltage applied to the source line SL, based on the source line control signal CTRL_SL.

The control logic 300 may control the peripheral circuit 200 by outputting the operation signal OP_CMD, the row decoder control signals AD_signals, the page buffer control signals PBSIGNALS, and the allow bit VRY_BIT<#> in response to the command CMD and the address ADD. Also, the control logic 300 may control the temperature detection circuit 400 by outputting a temperature detection control signal CTRL_TS when a command CMD corresponding to a program operation is received, and output or inactivate the temperature detection control signal CTRL_TS, based on a program elapsed time, when a command CMD corresponding to a read operation is received.

The control logic 300 may be configured to include the temperature compensation circuit 310. The temperature compensation circuit 310 may set a level of operating voltages Vop used in a program operation or a read operation, based on a temperature code temp_code received from the temperature detection circuit 400, and control the voltage generating circuit 210 to generate the operating voltages Vop having the set level. Also, the temperature compensation circuit 310 may set a precharge level of the bit lines BL1 to BLm in the program operation or the read operation, based on the temperature code temp_code, and control the page buffer group 230 to perform a precharge operation to the set precharge level.

Also, when a command CMD corresponding to the read operation is received from the memory controller 1200 shown in FIG. 1 after the program operation is completed, the temperature compensation circuit 310 may set a level of operating voltages Vop used in the read operation and set a precharge level of the bit lines BL1 to BLm, based on a temperature code temp_code received from the temperature detection circuit 400 to be stored in a register 311 just before the program operation, based on a program elapsed time, or set a level of operating voltages Vop used in the read operation and set a precharge level of the bit lines BL1 to BLm, based on a temperature code temp_code newly received from the temperature detection circuit 400.

The temperature compensation circuit 310 may include the register 311, a voltage control circuit 312, and a timer 313. The register 311 may store a temperature code temp_code received from the temperature detection circuit 400. Also, the register 311 may store program operation information indicating a time point at which a program operation is completed, a time point at which a command CMD corresponding to the program operation is received, a time point at which a temperature sensing operation is performed after the command CMD corresponding to the program operation is received, or the like. Also, the register 311 may store a temperature compensation table. The temperature compensation table may include a level of operating voltages and a precharge level of the bit lines, which correspond to each of a plurality of temperature codes.

The voltage control circuit 312 may set a level of operating voltages Vop used in a program operation and a precharge level of the bit lines BL1 to BLm, based on a temperature code temp_code received from the temperature compensation circuit 310 in the program operation and the temperature compensation table, control the voltage generating circuit 210 to generate the operating voltages Vop having the set level, and control the page buffer group 230 to perform a precharge operation to the set precharge level.

Also, the voltage control circuit 312 may set a level of operating voltages Vop used in a read operation and a precharge level of the bit lines BL1 to BLm, based on a temperature code temp_code received from the temperature compensation circuit 310 or a temperature code temp_code stored in the register 311 in the read operation, control the voltage generating circuit 210 to generate the operating voltages Vop having the set level, and control the page buffer group 230 to perform a precharge operation to the set precharge level.

When a command CMD corresponding to the read operation is received from the memory controller 1200 shown in FIG. 1 after the program operation is completed, the timer 313 may measure a program elapsed time indicating a time to a time point at which the command CMD corresponding to the read operation is received after the program operation is completed, a time from a time point at which the command CMD corresponding to the program operation is received to the time point at which the command CMD corresponding to the read operation is received, or a time from a time point at which a temperature sensing operation is performed to the time point at which the command CMD corresponding to the read operation is received, based on the program operation information stored in the register 311.

When the measured program elapsed time is equal to or shorter than a set time, the temperature compensation circuit 310 may determine that a temperature change of the memory device 1100 is inadequate, thereby setting the level of the operating voltages Vop used in the read operation and the precharge level of the bit lines BL1 to BLm, using the temperature code temp_code used in the program operation.

When the measured program elapsed time exceeds the set time, the temperature compensation circuit 310 may receive a new temperature code temp_code from the temperature detection circuit 400, and set the level of the operating voltages Vop used in the read operation and the precharge level of the bit lines BL1 to BLm, using the received temperature code temp_code.

The temperature detection circuit 400 may measure a temperature of the memory device 1100 in response to the temperature detection control signal CTRL_TS output from the control logic 300, and generate a temperature code temp_code by transforming the measured temperature into a digital code. A temperature measurement operation performed by the temperature detection operation 400 may overlap with a partial period of the program operation or a partial period of the read operation. The generated temperature code temp-code may be output to the temperature compensation circuit 310 of the control logic 300. The temperature detection circuit 400 may be disposed in an area adjacent to the memory cells. For example, the temperature detection circuit 400 may be disposed at a side or upside/downside of the memory cell array 100 or be disposed inside the memory cell array 100.

Although a temperature of the memory device 1100 just before a program operation is performed and a temperature of the memory device 1100 just before a read operation is performed are the same, a temperature code temp_code obtained as a result of a temperature measurement operation performed in the program operation and a temperature code temp_code obtained as a result of a temperature measurement operation performed in the read operation may be different from each other. The pump included in the voltage generating circuit 210 may differently operate in an activation period for the program operation and an activation period for the read operation, and accordingly, ground terminal noises of the memory device 1100, which are generated by a pumping operation of the pump in the program operation and the read operation, may be different from each other. A temperature code temp_code finally generated in a digital transformation operation of transforming the temperature of the memory device 1100, which is measured by the temperature detection circuit 400, into a digital code may be changed according to a ground terminal noise difference.

In the embodiment of the present disclosure described above, a case where a temperature code temp_code is generated by the temperature detection circuit 400 has been described as an example. However, the embodiments of the present disclosure are not limited thereto. In another embodiment, a temperature code temp_code may be received from an outside of the memory device 1100, e.g., the memory controller 1200 shown in FIG. 1, and the temperature compensation circuit 310 may set a level of operating voltages Vop used in a program operation or a read operation and a precharge level of the bit lines BL1 to BLm, based on the received temperature code temp_code.

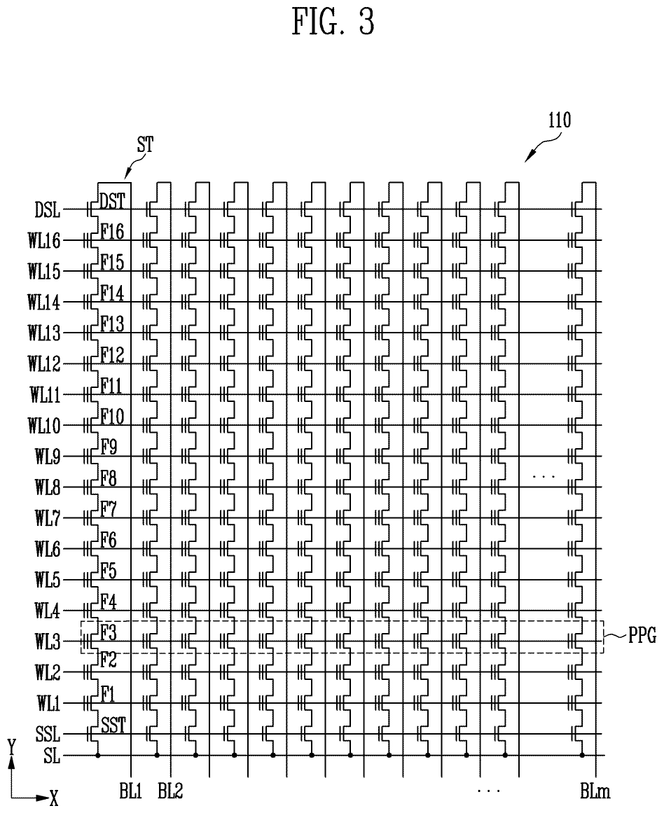

FIG. 3 is a diagram illustrating the memory block shown in FIG. 2.

Referring to FIG. 3, in the memory block 110, a plurality of word lines arranged in parallel to one another may be connected between a first select line and a second select line. The first select line may be a source select line SSL, and the second select line may be a drain select line DSL. More specifically, the memory block 110 may include a plurality of strings ST connected between bit lines BL1 to BLm and a source line SL. The bit lines BL1 to BLm may be connected to the strings ST, respectively, and the source line SL may be commonly connected to the strings ST. The strings ST may be configured identically to one another, and therefore, a string ST connected to a first bit line BL1 will be described in detail as an example.

The string ST may include a source select transistor SST, a plurality of memory cells F1 to F16, and a drain select transistor DST, which are connected in series between the source line SL and the first bit line BL1. At least one source select transistor SST and at least one drain select transistor DST may be included in one string ST, and a number of memory cells which is greater than the number of the memory cells F1 to F16 shown in the drawing may be included in the one string ST.

A source of the source select transistor SST may be connected to the source line SL, and a drain of the drain select transistor DST may be connected to the first bit line BL1. The memory cells F1 to F16 may be connected in series between the source select transistor SST and the drain select transistor DST. Gates of source select transistors SST included in different strings ST may be connected to the source select line SSL, gates of drain select transistors DST included in different strings ST may be connected to the drain select line DSL, and gates of memory cells F1 to F16 included in different strings ST may be connected to a plurality of word lines WL1 to WL16. A group of memory cells connected to the same word line among memory cells included in different strings ST may be referred as a page PPG. Therefore, a number of pages PPG which corresponds to the number of the word lines WL1 to WL16 may be included in the memory block 110.

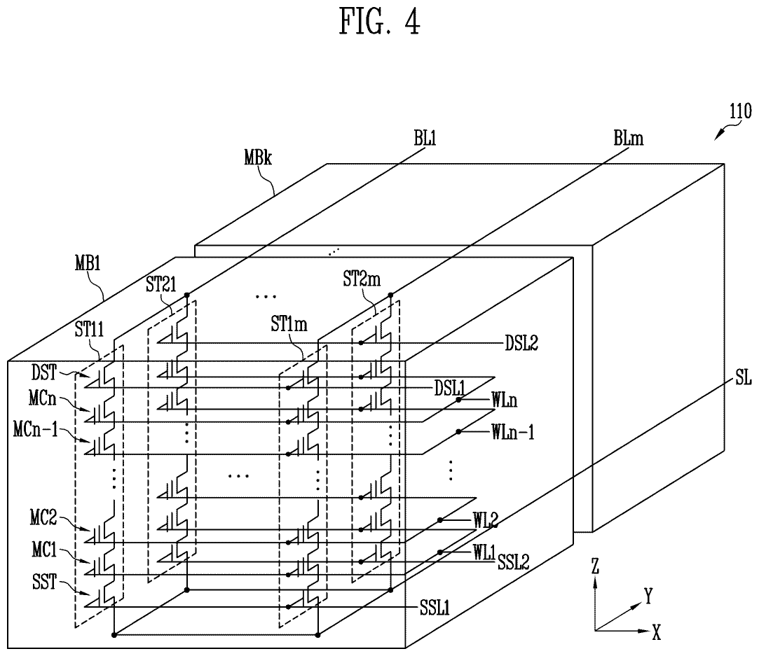

FIG. 4 is a diagram illustrating a three-dimensionally configured memory block in accordance with an embodiment of the present disclosure.

Referring to FIG. 4, the memory cell array 100 may include a plurality of memory blocks MB1 to MBk 110. The memory block 110 may include a plurality of strings ST11 to ST1m and ST21 to ST2m. In an embodiment, each of the plurality of strings ST11 to ST1m and ST21 to ST2m may be formed in an ‘I’ shape or a ‘U’ shape. In a first memory block MB1, m strings may be arranged in a row direction (X direction). Although a case where two strings are arranged in a column direction (Y direction) is illustrated in FIG. 4, this is for convenience of description, and three or more strings may be arranged in the column direction (Y direction).

Each of the plurality of strings ST11 to ST1m and ST21 to ST2m may include at least one source select transistor SST, first to nth memory cells MC1 to MCn, and at least one drain select transistor DST.

The source select transistor SST of each string may be connected between a source line SL and memory cells MC1 to MCn. Source select transistors of strings arranged on the same row may be connected to the same source select line. Source select transistors of strings ST11 to ST1m arranged on a first row may be connected to a first source select line SSL1. Source select transistors of strings ST21 to ST2m arranged on a second row may be connected to a second source select line SSL2. In another embodiment, the source select transistors of the strings ST11 to ST1m and ST21 to ST2m may be commonly connected to one source select line.

The first to nth memory cells MC1 to MCn of each string may be connected in series to each other between the source select transistor SST and the drain select transistor DST. Gates of the first to nth memory cells MC1 to MCn may be respectively connected to first to nth word lines WL1 to WLn.

In an embodiment, at least one of the first to nth memory cells MC1 to MCn may be used as a dummy memory cell. When the dummy memory cell is provided, a voltage or current of a corresponding string can be stably controlled. Accordingly, the reliability of data stored in the memory block 110 can be improved.

The drain select transistor DST of each string may be connected between a bit line and the memory cells MC1 to MCn. Drain select transistors DST of strings arranged in the row direction may be connected to a drain select line extending in the row direction. Drain select transistors DST of the strings ST11 to ST1m on the first row may be connected to a first drain select line DSL1. Drain select transistors DST of the strings ST21 to ST2m on the second row may be connected to a second drain select line DSL2.

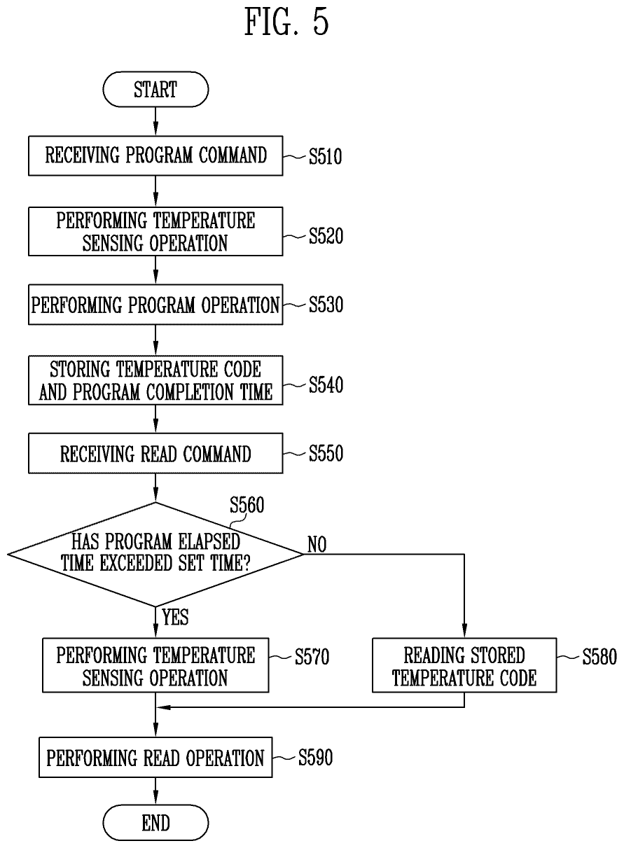

FIG. 5 is a flowchart illustrating a program operation and a read operation of the memory device shown in FIG. 2.

A program operation and a read operation of the memory device in accordance with an embodiment of the present disclosure will be described as follows with reference to FIGS. 2 to 5.

In operation S510, a command CMD, an address ADD, and data DATA to be programmed, which correspond to a program operation, may be received to the memory device 1100 from an outside (e.g., the memory controller 1200 shown in FIG. 1).

The input/output circuit 250 of the memory device 1100 receive the command CMD and the address ADD, which correspond to the program operation, from the outside, and transmit the received command CMD and the received address ADD to the control logic 300.

In operation S520, the temperature detection circuit 400 may perform a temperature sensing operation in response to the command CMD corresponding to the program operation. For example, the temperature detection circuit 400 may measure a temperature of the memory device 1100 or a temperature of the memory cell array 100, and generate a temperature code temp_code by transforming the measured temperature into a digital code. In another embodiment, the temperature code temp_code may be received from the outside of the memory device 1100, e.g., the memory controller 1200.

In operation S530, the control logic 300 may receive the temperature code temp_code from the temperature detection circuit 400, and set a level of operating voltages Vop used in the program operation or a precharge level of the bit lines BL1 to BLm, based on the temperature code temp_code. The peripheral circuit 200 may perform the program operation, using the operating voltages Vop having the set level and the set precharge level of the bit lines BL1 to BLm.

The program operation may include a program voltage apply operation and a program verify operation.

The program voltage apply operation will be described as follows. The page buffers PB1 to PBm 231 of the page buffer group 230 may

precharge the bit lines BL1 to BLm to a set level under the control of the voltage control circuit 321, and then apply a program allow voltage (e.g., a ground voltage) or a program inhibit voltage (e.g., a power voltage) to each of the bit lines BL1 to BLm, based on arbitrarily stored data DATA to be programmed.

The voltage generating circuit 210 may generate a program voltage used in the program operation and a program pass voltage in response to the operation signal OP_CMD. The voltage generating circuit 210 may generate a level of the program voltage and the program pass voltage to have a set level under the control of the voltage control circuit 321.

The row decoder 220 may transfer operating voltages Vop generated by the voltage generating circuit 210 to local lines LL connected to a selected memory block 110 in response to the row decoder control signals AD_signals. For example, the row decoder 220 may apply the program voltage generated by the voltage generating circuit 210 to a selected word line of the selected memory block 110 and apply the program pass voltage generated by the voltage generating circuit 210 to unselected word lines of the selected memory block 110 in response to the row decoder control signals AD_signals.

The program verify operation may be performed after the program voltage apply operation is completed. The program verify operation will be described as follows.

The temperature compensation circuit 310 of the control logic 300 may set a level of operating voltages Vop used in the program verify operation and set a precharge level of the bit lines BL1 to BLm, based on the temperature code temp_code. For example, the voltage control circuit 312 of the temperature compensation circuit 310 may load a temperature compensation table stored in the register 311, and set a level of operating voltages Vop used in the program verify operation, e.g., a verify voltage applied to a selected word line in the program verify operation and a verify pass voltage applied to unselected word lines in the program verify operation and set a precharge level of the bit lines BL1 to BLm, based on the loaded temperature compensation table and the temperature code temp_code. Also, the voltage control circuit 312 may control the voltage generating circuit 210 to generate the operating voltages Vop having the set level and control the page buffer group 230 to perform a precharge operation to the set precharge level.

The page buffers PB1 to PBm 231 of the page buffer group 230 may precharge the bit lines BL1 to BLm to the set level under the control of the voltage control circuit 312.

The voltage generating circuit 210 may generate a verify operation used in the program verify operation and a verify pass voltage in response to the operation signal OP_CMD. The voltage generating circuit 210 may generate a level of the verify voltage and the verify pass voltage to have a set level under the control of the voltage control circuit 312.

The row decoder 220 may transfer operating voltages Vop generated by the voltage generating circuit 210 to local lines LL connected to a selected memory block 110 in response to the row decoder control signals

AD_signals. For example, the row decoder 220 may apply the verify voltage generated by the voltage generating circuit 210 to a selected word line of the selected memory block 110 and apply the verify pass voltage generated by the voltage generating circuit 210 to unselected word lines of the selected memory block 110 in response to the row decoder control signals AD_signals.

The page buffers PB1 to PBm 231 may sense a potential level or a current amount of the bit lines BL1 to BLm, and determine pass or fail of the program operation, based on a sensing result and arbitrarily stored data to be programmed.

In operation S540, when the above-described program operation is completed, the temperature compensation circuit 310 stores, in the register 311, program end information indicating a time point at which the program operation is completed. Also, the temperature compensation circuit 310 may store, in the register 311, a temperature code temp_code used in the program operation. For example, when a program operation corresponding to one program command is completed, the temperature compensation circuit 310 may store, in the register 311, a temperature code temp_code used in the completed program operation. Therefore, one temperature code temp_code may correspond to one program command. In addition, a program operation corresponding to one program command may be a program operation corresponding to at least one page among a plurality of pages included in a memory block.

In operation S550, after the program operation is completed, a command CMD and an address ADD, which correspond to a read operation, may be received from the outside (e.g., the memory controller 1200 shown in FIG. 1). The input/output circuit 250 of the memory device 1100 may receive the command CMD and the address ADD, which correspond to the read operation, and transmit the received command CMD and the received address ADD to the control logic 300.

In operation S560, when the command CMD corresponding to the read operation is received from the memory controller 1200 shown in FIG. 1 after the program operation is completed, the temperature compensation circuit 310 may determine whether a program elapsed time has exceeded a set time.

For example, the timer 313 may measure a program elapsed time indicating a time to a time point at which the command CMD corresponding to the read operation is received after the program operation is completed, a time from a time point at which the command CMD corresponding to the program operation is received to the time point at which the command CMD corresponding to the read operation is received, or a time from a time point at which a temperature sensing operation is performed to the time point at which the command CMD corresponding to the read operation is received, based on the program operation information stored in the register 311.

In operation S570, when the program elapsed time has exceeded the set time as a determination result of the above-described operation S560, the control logic 300 may control the temperature detection circuit 400 to perform a new temperature sensing operation, and the temperature detection circuit 400 may output a new temperature code temp_code to the temperature compensation circuit 310 by performing the new temperature sensing operation under the control of the control logic 300.

The temperature compensation circuit 310 may set a level of operating voltages Vop used in the read operation or a precharge level of the bit lines BL1 to BLm, based on the new temperature code temp_code received from the temperature detection circuit 400.

In operation S580, when the time to the time point at which the command CMD corresponding to the read operation is received after the program operation is completed is within the set time as a determination result of the above-described operation S560, the temperature compensation circuit 310 may load a temperature code temp_code stored in the register 311, and set a level of the operating voltages Vop used in the read operation and a precharge level of the bit lines BL1 to BLm, based on the loaded temperature code temp_code.

The temperature detection circuit 400 may perform a temperature measurement operation in response to the command CMD corresponding to the read operation, but the temperature compensation circuit 310 may block the new temperature code temp_code received from the temperature detection circuit 400.

In operation S590, the read operation may be performed, using the operating voltages Vop having the set level and the precharge level of the bit lines BL1 to BLm, by the temperature compensation circuit 310.

For example, the voltage control circuit 312 may control the voltage generating circuit 210 to generate the operating voltages Vop having the set level, and control the page buffer group 230 to perform the precharge operation to the set precharge set.

The page buffers PB1 to PBm 231 of the page buffer group 230 may precharge the bit lines BL1 to BLm to set level under the control of the voltage control circuit 312.

The voltage generating circuit 210 may generate a read voltage applied to a selected word line used in the read operation and a read pass voltage applied to unselected word lines in response to the operation signal OP_CMD. The voltage generating circuit 210 may generate a level of the read voltage and the read pass voltage to have a set level under the control of the voltage control circuit 312.

The row decoder 220 may transfer operating voltages Vop generated by the voltage generating circuit 210 to local lines LL connected to a selected memory block 110 in response to the row decoder control signals AD_signals. For example, the row decoder 220 may apply the read voltage generated by the voltage generating circuit 210 to a selected word line of the selected memory block 110 and apply the read pass voltage generated by the voltage generating circuit 210 to unselected word lines of the selected memory block 110 in response to the row decoder control signals AD_signals.

The page buffers PB1 to PBm 231 may sense data stored in memory cells included in the selected memory block 110 by sensing a potential level or a current amount of the bit lines BL1 to BLm.

As described above, in accordance with the embodiment of the present disclosure, when the command corresponding to the read operation is received within a certain time after the program operation is completed, it is determined that a temperature change in the program operation and the read operation is not large, and thus a temperature code obtained in a temperature detection operation performed for the program operation can also be used for the read operation.

In the embodiment of the present disclosure described above, a case where the read operation is performed after the program operation is performed has been described as an embodiment. However, the embodiments of the present are not limited thereto. When a plurality of general operations (a program operation, a read operation, an erase operation, and the like) are sequentially performed, operating voltages and a bit line precharge level may be set by using, in a next general operation, a temperature code obtained in a previous general operation, based on a time to a time point at which a command corresponding to the next general operation is received after one general operation is completed, or by using a new temperature code obtained by a new temperature measurement operation.

For example, when a command corresponding to a program operation is received after a read operation is completed, operating voltages and a bit line precharge level may be set by using, even in the program operation, a temperature code used in the read operation when a time to a time point at which the command corresponding to the program operation is received after the read operation is completed is within a set time.

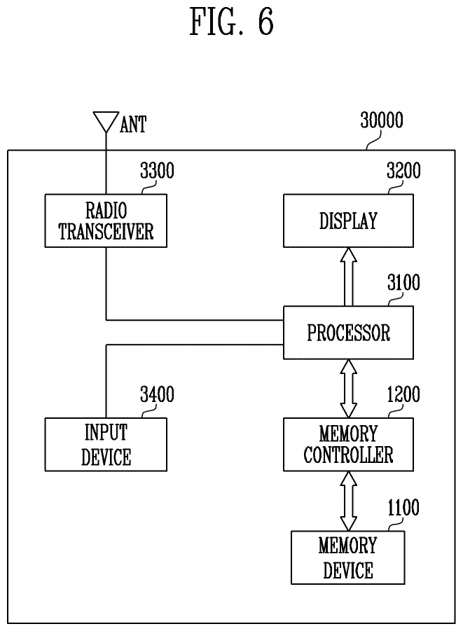

FIG. 6 is a diagram illustrating a memory system 30000 in accordance with an embodiment of the present disclosure.

Referring to FIG. 6, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like under the control of a processor 3100.

Data programmed in the memory device 1100 may be output through a display 3200 under the control of the memory controller 1200 and the processor 3100.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the memory controller 1200 or the display 3200.

The memory controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mouse, a keypad, or a keyboard.

The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100. In addition, the memory controller 1200 may be implemented as an embodiment of the memory controller 1200 shown in FIG. 1, and the memory device 1100 may be implemented as an embodiment of the memory device 1100 shown in FIG. 2.

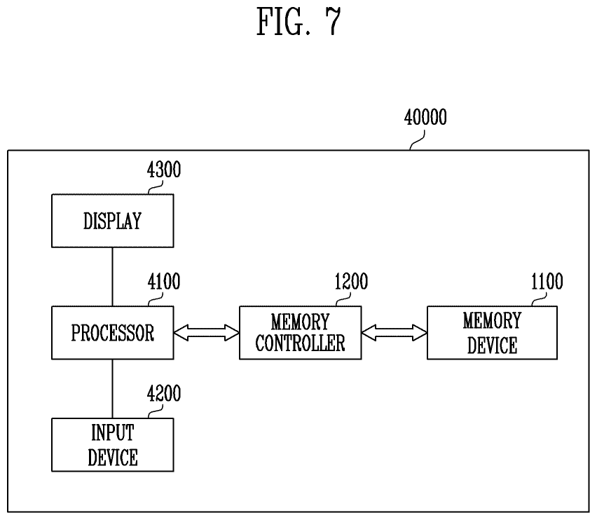

FIG. 7 is a diagram illustrating a memory system 40000 in accordance with an embodiment of the present disclosure.

Referring to FIG. 7, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100. In addition, the memory controller 1200 may be implemented as an embodiment of the memory controller 1200 shown in FIG. 1, and the memory device 1100 may be implemented as an embodiment of the memory device 1100 shown in FIG. 2.

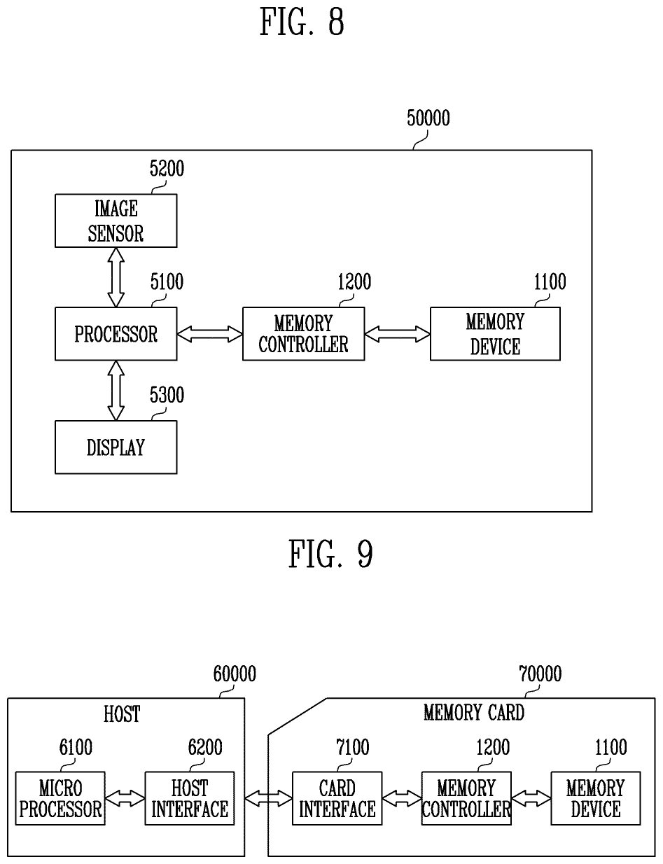

FIG. 8 is a diagram illustrating a memory system 50000 in accordance with an embodiment of the present disclosure.

Referring to FIG. 8, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the memory controller 1200. Under the control of the processor 5100, the converted digital signals may be output through a display 5300, or be stored in the memory device 1100 through the memory controller 1200. In addition, data stored in the memory device 1100 may be output through the display 5300 under the control of the processor 5100 or the memory controller 1200.

In some embodiments, the memory controller 1200 capable of controlling an operation of the memory device 1100 may be implemented as a part of the processor 5100, or be implemented as a chip separate from the processor 5100. In addition, the memory controller 1200 may be implemented as an embodiment of the memory controller 1200 shown in FIG. 1, and the memory device 1100 may be implemented as an embodiment of the memory device 1100 shown in FIG. 2.

FIG. 9 is a diagram illustrating a memory system 70000 in accordance with an embodiment of the present disclosure.

Referring to FIG. 9, the memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In some embodiments, the card interface 7100 may be a secure digital (SD) card interface or a multi-media card (MMC) interface, but the embodiments of the present disclosure are not limited thereto. In addition, the memory controller 1200 may be implemented as an embodiment of the memory controller 1200 shown in FIG. 1, and the memory device 1100 may be implemented as an embodiment of the memory device 1100 shown in FIG. 2.

The card interface 7100 may interface data exchange between a host 60000 and the memory controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

In accordance with an embodiment of the present disclosure, when a command corresponding to a read operation is received within a set time after a program operation is performed, the read operation is performed using a temperature code used in the program operation, so that the read operation can advantageously be performed without any error of a temperature measurement operation.

While embodiments of the present disclosure have been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all operations may be selectively performed or part of the operations may be omitted. In each embodiment, the operations are not necessarily performed in accordance with the described order and may be rearranged. The embodiments disclosed in this specification and drawings are only examples to facilitate an understanding of the present disclosure, and the embodiments of the present disclosure are not limited thereto. That is, it should be apparent to those skilled in the art that various modifications can be made based on the technological scope of the present disclosure.

The embodiments of the present disclosure have been described in the drawings and specification. Although specific terminologies are used here, those are only to describe the embodiments of the present disclosure. Therefore, the embodiments of the present disclosure are not restricted to the above-described embodiments and many variations are possible within the spirit and scope of the present disclosure. It should be apparent to those skilled in the art that various modifications can be made based on the technological scope of the present disclosure in addition to the embodiments disclosed herein. Furthermore, the embodiments may be combined to from additional embodiments.

What is claimed is:

1. A memory device comprising:
a memory cell array including a plurality of memory cells;
a peripheral circuit configured to perform a program operation and a read operation on the plurality of memory cells;
a temperature detection circuit configured to generate a temperature code by measuring a temperature of the memory cell array after a program command is externally received; and
a control logic configured to set, based on the temperature code, at least one of a level of operating voltages and a bit line precharge level, and control, in response to the program command, the peripheral circuit to perform the program operation on the plurality of memory cells, using at least one of the level of the operating voltages and the bit line precharge level,
wherein, when a read command is externally received after completing the program operation and a program elapsed time is within a set time, the control logic is configured to set at least one of a level of operating voltages and a bit line precharge level which are to be used in a read operation corresponding to the read command, based on the temperature code generated after receiving the program command.

2. The memory device of claim 1,
wherein the control logic includes a temperature compensation circuit configured to set, based on the temperature code, at least one of the level of the operating voltages and the bit line precharge level after receiving the program command, and
wherein, when the read command is received after the set time elapses, the temperature compensation circuit is configured to receive a new temperature code from the temperature detection circuit, and set, based on the received new temperature code, at least one of the level of the operating voltages and the bit line precharge level which are to be used in the read operation.

3. The memory device of claim 2, wherein the temperature compensation circuit includes:
a register configured to store the temperature code received from the temperature detection circuit;
a timer configured to measure the program elapsed time; and
a voltage control circuit configured to set, based on the temperature code and a temperature compensation table, at least one of the level of the operating voltages and the bit line precharge level, used in the program operation or the read operation, and control the peripheral circuit to perform the program operation and the read operation, using at least one of the set level of the operating voltages and the bit line precharge level, used in the program operation or the read operation.

4. The memory device of claim 3,
wherein the register stores the temperature compensation table and program operation information indicating at least one of a time point of completion of the program operation, a time point of reception of the program command, and a time point of measurement of the temperature after receiving the program command, and
wherein the timer is configured to measure the program elapsed time, based on the program operation information stored in the register and a time point of reception of the read command is received.

5. The memory device of claim 4, wherein, when the read command is received, the temperature compensation circuit is configured to
load the program operation information stored in the register,
measure the program elapsed time based on the loaded program operation information and the time point of reception of the read command, and
check whether the read command is received within the set time, based on the measured program elapsed time.

6. The memory device of claim 4, wherein the temperature detection circuit is configured to measure the temperature of the memory cell array, and generate the temperature code by transforming the measured temperature into a digital code.

7. The memory device of claim 1, wherein the program elapsed time is one of:
a time from a time point of completion of the program operation to a time point of reception of the read command;
a time from a time point of measurement of the temperature after receiving the program command to a time point of reception of the read command; and
a time from a time point of reception of the program command to a time point of reception of the read command.

8. The memory device of claim 1, wherein the control logic is configured to:
control the temperature detection circuit to generate the new temperature code when the program elapsed time exceeds the set time; and
set, based on the new temperature code, at least one of the level of the operating voltages and the bit line precharge level, to be used in the read operation.

9. A method of operating a memory device, the method comprising:
receiving a first command corresponding to a first operation;
measuring, after the first command is received, a temperature inside the memory device;
generating a first temperature code corresponding to the measured temperature;
setting first operating voltages used in the first operation, based on the first temperature code;
performing the first operation using the set first operating voltages;
setting second operating voltages used in a second operation based on the first temperature code, when a second command corresponding to the second operation is received within a set time after completing the first operation; and
performing the second operation using the set second operating voltages.

10. The method of claim 9, further comprising, when the second command corresponding to the second operation is received, exceeding the set time, after completing the first operation:
newly measuring a temperature inside the memory device;
generating a second temperature code corresponding to the newly measured temperature;
setting the second operating voltages used in the second operation, based on the second temperature code; and
performing the second operation, using the set second operating voltages.

11. The method of claim 9, further comprising storing the first temperature code in a register of the memory device when completing the first operation.

12. The method of claim 11, further comprising storing, in the internal register, end time information indicating a time point of completion of the first operation.

13. The method of claim 9, wherein the generating the first temperature code comprises transforming the measured temperature into a digital code to generate the first temperature code.

14. The method of claim 9,
wherein the setting the first operating voltages comprises setting a bit line precharge level based on the first temperature code, and
wherein performing the first operation comprises performing the first operation using the set bit line precharge level.

15. The method of claim 9,
wherein setting the second operating voltages comprises setting a bit line precharge level based on the first temperature code, and
wherein performing the second operation comprises performing the second operation using the set bit line precharge level.

16. A method of operating a memory device, the method comprising:
receiving a first command corresponding to a program operation;
measuring a temperature inside the memory device;
generating a first temperature code corresponding to the measured temperature;
setting first operating voltages used in the program operation, based on the first temperature code;
performing the program operation using the set first operating voltages;
receiving a second command corresponding to a read operation after completing the program operation;
measuring a program elapsed time according to a time point of reception of the second command;
setting second operating voltages to be used in the read operation, using the first temperature code; and
performing the read operation using the set second operating voltages when the program elapsed time is within a set time.

17. The method of claim 16, wherein setting the second operating voltages comprises, when the second command is received within a set time after completing the program operation, setting the second operating voltages to be used in the read operation using the first temperature code.

18. The method of claim 16, further comprising, when the program elapsed time exceeds the set time:
newly measuring a temperature inside the memory device;
generating a second temperature code based on the newly measured temperature; and
setting the second operating voltages based on the second temperature code.

19. The method of claim 16, wherein the program elapsed time is one of:
a time from a time point of completion of the program operation to the time point of reception of the second command;
a time from a time point of generation of the first temperature code to a time point of completion of the second command is received; and
a time from a time point of reception of the first command to the time point of reception of the second command.

20. The method of claim 16, further comprising storing the first temperature code in a register of the memory device when completing the program operation.

21. The method of claim 19, further comprising storing, in the register, program operation information indicating at least one of the time point of completion of the program operation, the time point of reception of the first command, and the time point of generation of the first temperature code.

22. The method of claim 16, wherein generating the first temperature code comprises transforming the measured temperature into a digital code to generate the first temperature code.

23. The method of claim 16,
wherein setting the first operating voltages comprises setting a bit line precharge level based on the first temperature code, and
wherein performing the program operation comprises performing the program operation using the set bit line precharge level.

24. A memory device comprising:
a memory block;
a voltage generating circuit configured to apply operating voltages to word lines of the memory block in a program operation and a read operation on the memory block;
a page buffer group configured to precharge bit lines of the memory block in the program operation and the read operation;
a temperature detection circuit configured to generate a first temperature code by measuring a temperature inside the memory device after receiving a program command, and generate a second temperature code by newly measuring a temperature inside the memory device when a read command corresponding to the read operation is received, exceeding a set time, after completing the program operation; and
a control logic configured to set, based on the first temperature code or the second temperature code, at least one of a level of the operating voltages and a bit line precharge level, and control, in response to the program command or the read command, the voltage generating circuit and the page buffer group to perform the program operation or the read operation, using at least one of the set level of the operating voltages and the set bit line precharge level,
wherein, when the read command corresponding to the read operation is received within the set time after completing the program operation, the control logic is configured to set at least one of the level of operating voltages and the bit line precharge level which are to be used in the read operation, based on the first temperature code.
